(19) United States
(12) Patent Application Publication
(10) Pub. No.: US 2009/0051571 A1
(43) Pub. Date: Feb. 26, 2009

(54) KEYPAD

(75) Inventor: CHIEN-KUO TANG, Taipei County (TW)

Correspondence Address: ROSENBERG, KLEIN & LEE, 3458 ELLICOTT CENTER DRIVE-SUITE 101, ELLICOTT CITY, MD, 21043, US

(73) Assignee: URC ELECTRONIC TECHNOLOGY (KUNSHAN) CO., LTD., JIANGSU (CN)

(21) Appl. No.: 11/843,915

(22) Filed: Aug. 23, 2007

(51) Int. Cl. H03M 11/00

(52) U.S. Cl. 341/22

(57) ABSTRACT

A keyboard is disclosed. The keyboard consists of a circuit board, a plurality of metal dome and a button set. The plurality of metal domes is arranged on the circuit board and is electrically coupled to the circuit board. The button set is composed of a plurality of buttons that respectively are corresponding to the metal domes. A piece of leather or cloth is disposed on the button set so as to make users have good sense of touch and prevent figures from being worn or falling off. Thus the aesthetic appeal is improved. Moreover, a supporting frame is disposed on the bottom set so as to prevent the buttons with leather or cloth from moving along with other buttons being pressed. Furthermore, a lighting device is added into the device for projecting light onto surface of the button set. Thus users can operate the buttons under dingy environment.

### BACKGROUND OF THE INVENTION

The present invention relates to a keypad, especially to a keypad with leather or cloth.

Along with fast development of modern technology, people have higher requirement for electronic products such as household appliances, digital electronics and communication products. They have not only dazzling appearances but also variety and diversity of functions. For example, sales volume of mobile phones grows dramatically due to progress of communication technology. Thus manufactures face fierce competition and dedicate to develop mobile phones with more advanced functions and novel design so as to attract consumers. The trend for mobile phone design and compact and light-weight. For example, Motorola has rolled out mobile phones named Razr debut in 2004 and it's sold well with sales volume of fifty million. Thus it is learned that appearance is an important consideration for consumers whiling buying mobile phones. Besides function and price, fashion look is an even more important factor.

As to electronics, keypad is essential for operation of electronics. Conventional keypad is made from plastic so that the appearance is bad and sense of touch is poor. This lead to negative effect on users' feelings. Moreover, figures printed on plastic keypad is easy to fall off and it's inconvenient for users.

### SUMMARY OF THE INVENTION

Therefore it is a primary object of the present invention to provide a keypad that is disposed with leather or cloth so as to provide finer touch feelings and prevent the figures thereon from being worn or falling off. Thus the aesthetic appeal of the keypad is increased and users have good feelings about the device after using the device.

It is another object of the present invention to provide a keypad that is arranged with at least one supporting frame for preventing buttons with leather or cloth on the keypad from moving along with other buttons that may cause operation errors.

It is a further object of the present invention to provide a keypad that is disposed with a lighting device that emits light to the keypad for convenience of users operating the device in the dark.

In order to achieve above objects, a keypad according to the present invention includes a circuit board, a plurality of metal domes, and a button set. The plurality of metal domes is arranged on the circuit board and is electrically connected with the circuit board. The button set consists of a plurality of buttons that respectively correspond to the metal domes. A piece of leather or cloth is disposed on the button set. Moreover, a figure layer having a plurality of figures is arranged on the leather or the cloth while the plurality of figures corresponds to the button set.

In order to prevent the buttons from moving along with other buttons being pressed, a supporting frame with a plurality of holes is disposed on the button set and the holes respectively correspond to each of the buttons. Furthermore, the keypad further includes a lighting device that projects light on the button set so that users can operate the devices conveniently even in a dingy or dark place.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a cross sectional view of an embodiment according to the present invention;

FIG. 1B is a top view of an embodiment according to the present invention;

FIG. 2A is a cross sectional view of another embodiment according to the present invention;

FIG. 2B is a top view of another embodiment according to the present invention;

FIG. 3A is a perspective view of a further embodiment according to the present invention;

FIG. 3B is a cross sectional view of the embodiment shown in the FIG. 3A;

FIG. 4A is a perspective view of a further embodiment according to the present invention;

FIG. 4B is a cross sectional view of the embodiment shown in the FIG. 4A.

### DETAILED DESCRIPTION OF THE PREFERRED EMBODIMENT

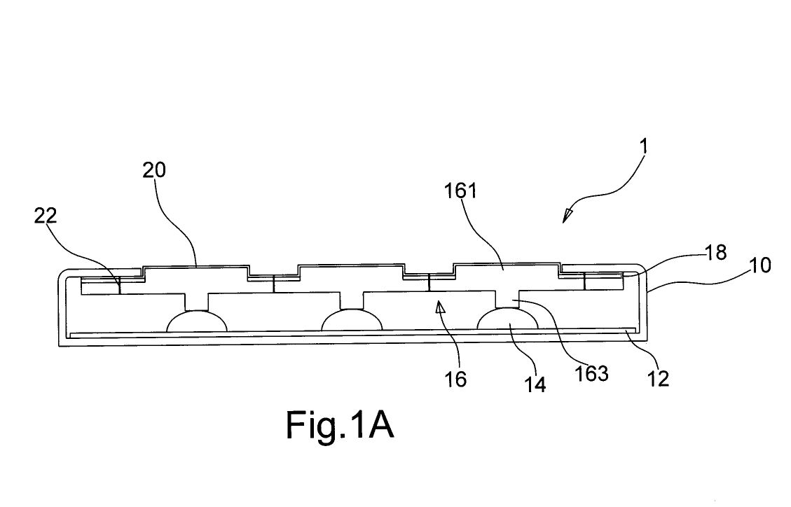

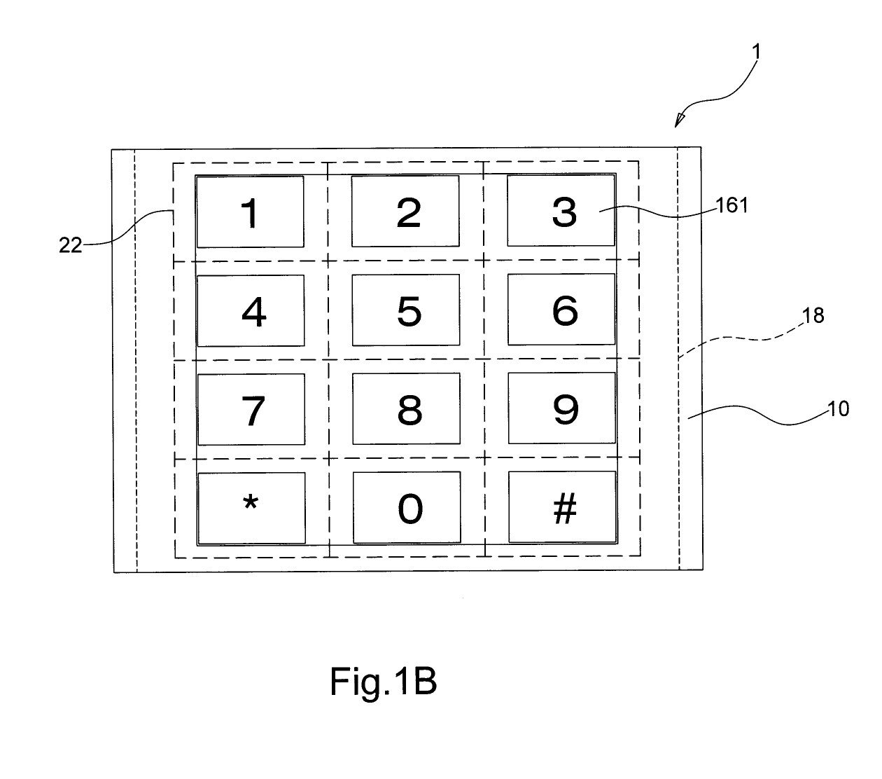

Refer to FIG. 1A & FIG. 1B, a keypad 1 according to the present invention consists of a circuit board 12, a plurality of metal domes 14, and a button set 16. The plurality of metal domes 14 is arranged on the circuit board 12 and is electrically coupled to the circuit board 12. The button set 16 is composed of a plurality of buttons 161 that respectively are corresponding to the metal domes 14. A piece of leather 20 is disposed on the button set 16 and is covered on surface of the buttons 161. The leather 20 can be replaced with cloth. The way for disposing the leather 20 (or cloth) on the button set 16 is sewing, as shown in FIG. 1B. Circumference of each button 161 is sewed with threads 22. The leather 20 (or cloth) can also be glued on surface of the button set 16.

The buttons 161 of the keypad 1 are all convex buttons. The button set 16 includes a plurality of projecting posts 163 that respectively are arranged on the buttons 161, corresponding to the metal domes 14. The projecting posts 163 are integrated with the buttons 161. The button set 16 is made from rubber. Moreover, a figure layer (not shown in the figure) is arranged on the leather 20 (or cloth) on surface of the button set 16. The figure layer having a plurality of figures and each figure corresponds to each button 161. The figures may be numbers or function icons. The above figure layer can be disposed on the leather 20 (or cloth) by laser marking, branding or transfer printing.

In order to prevent the button 161 from moving along with other buttons 161 being pressed, at least one supporting frame 18 having a plurality of holes (not shown in the figure) is disposed on the button set 16. The plurality of holes respectively corresponds to the buttons 161 so that the buttons 161 insert through those holes. The supporting frame 18 locates among those buttons 161 and is disposed between the buttons 161 and the leather (or cloth) 20. The supporting frame 18 supports other buttons 161 when one of the buttons 161 is pressed by users so as to avoid other buttons 161 moving along with the pressed button 161 that lead to operation errors. The supporting frame 18 is made from polycarbonate (PC). Moreover, a fixing frame 10 is used to fix the button set 16. The fixing frame 10 can be a housing of the electronics while the circuit board 12, the plurality of metal domes 14, and the button set 16 are all arranged inside the fixing frame 10.

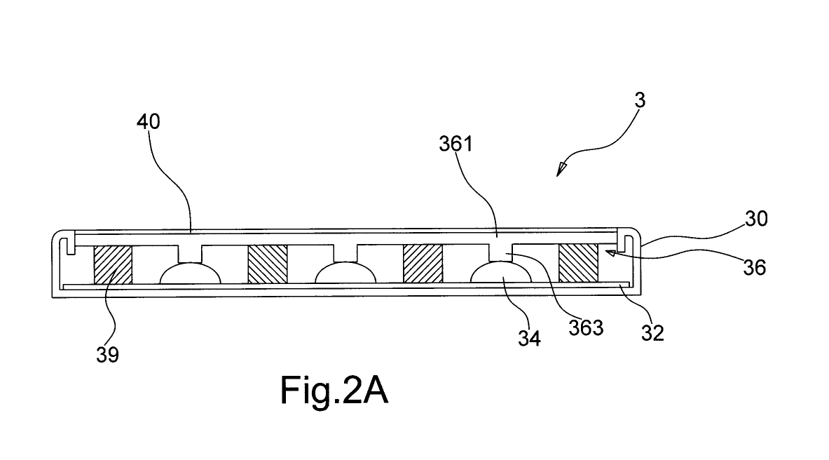

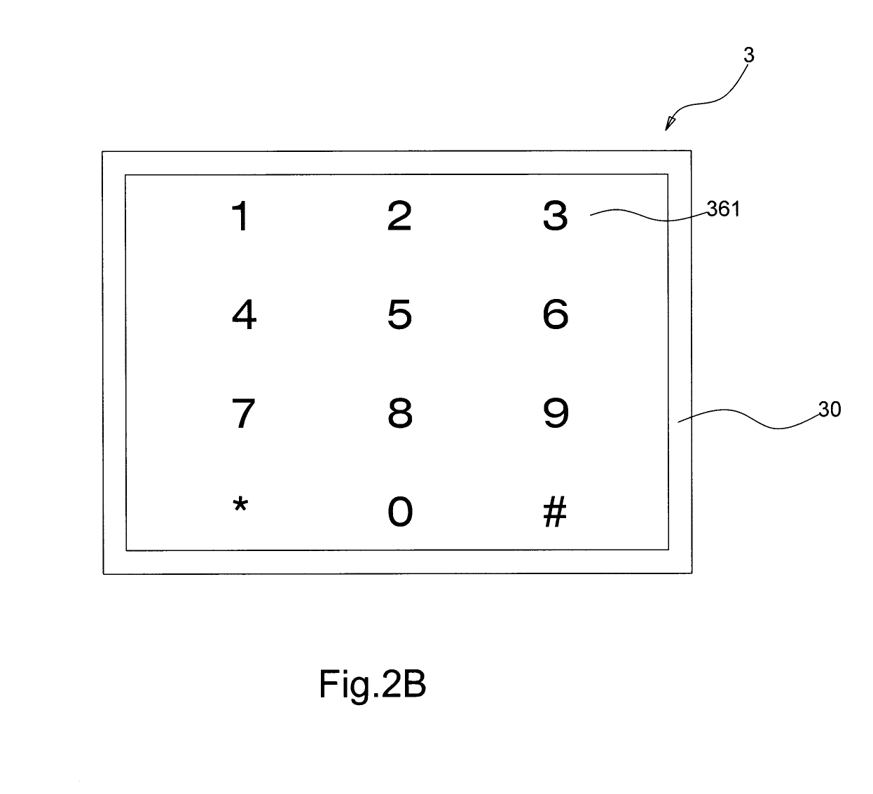

Refer to FIG. 2A & FIG. 2B, another embodiment of the present invention is disclosed. A keypad 3 according to the present invention includes a circuit board 32, a plurality of metal domes 34, and a button set 36 disposed with a piece of leather (or cloth) 40. The bottom set 35 consists of a plurality of buttons 361. The buttons 361 are flat buttons with projecting post 363. The buttons 361 are integrated with the projecting post 363. The leather (or cloth) 40 is glued or sewed on the button set. Moreover, a figure layer (not shown in figure) having a plurality of figures is disposed on the leather (or cloth) 40 by laser marking, branding or transfer printing. The plurality of figures such as numbers or function icons corresponds to the buttons 361. For fixing the button set 36, a glue member 39 is used to fix the button set 36 on the circuit board 32. Furthermore, a fixing frame 30 is also used to enhance fixing of the button set 36. The fixing frame 30 can be a housing of the electronics that accommodates the circuit board 32, the plurality of metal domes 34, and the button set 36 on the leather (or cloth) 40 therein. Moreover, a supporting frame is disposed on the button set 36 so as to prevent the buttons 361 from moving along with other buttons 361 pressed by the users.

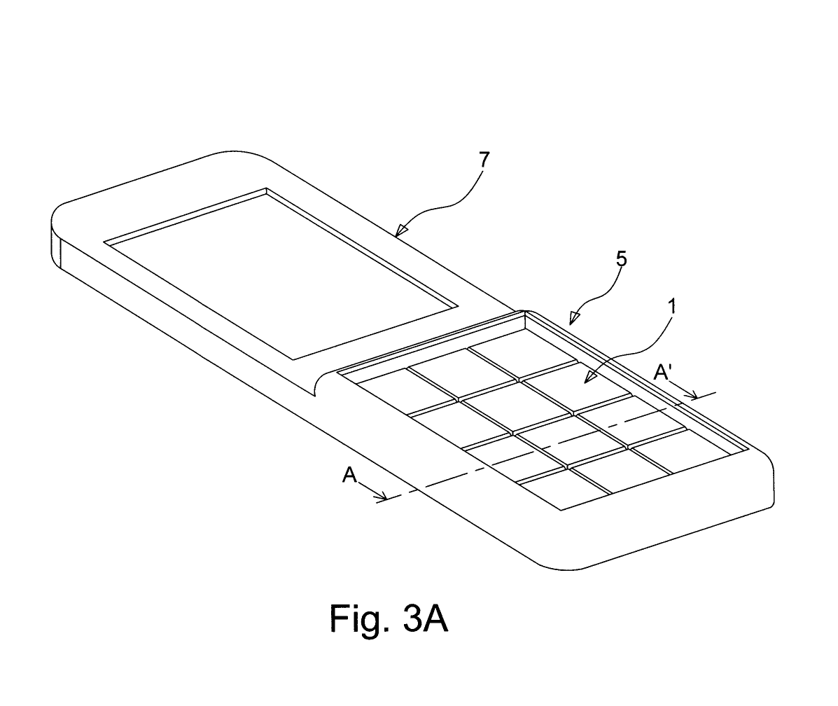

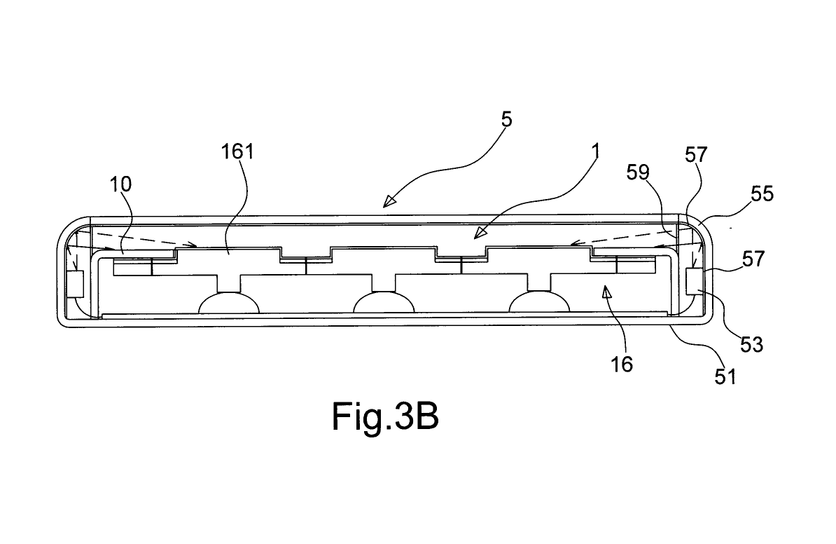

Refer to FIG. 3A & FIG. 3B, a keypad 1 with a lighting device 5 of an embodiment according to the present invention is disclosed. The device is applied to mobile phones. As shown in figure, the difference between this embodiment and the embodiment in FIG. 1 is in that this embodiment further includes a lighting device 5 that projects light on surface of the button set 16 so that users can read figures on the button set 16 under dingy surroundings.

The lighting device 5 includes an outer housing 51 and a plurality of light emitting members 53. The fixing frame 10 of the keypad 1 for fixing the button set 16 is arranged inside the outer housing 51. The plurality of light emitting members 53 is disposed on the outer housing 51, surrounding the button set 16, and is electrically coupled to the circuit board 12. A side wall of the outer housing 51 extends to form a circular reflection plane 55 so that light from the light emitting member 53 reflects by the circular reflection plane 55 and projects onto surface of the button set 16 for illuminating the buttons 161. A reflecting piece 57 is arranged on one side of the circular reflection plane 55 as well as one side of the outer housing 51 that corresponds to the button set 16 so as to prevent the side wall of the circular reflection plane 55 as well as the outer housing 51 from absorbing light energy. Thus the light reflective efficiency is improved. In addition, a light homogenizing piece 59 is disposed on the circular reflection plane 55 so as to filter the projected light and thus the light is projected onto the button set 16 evenly.

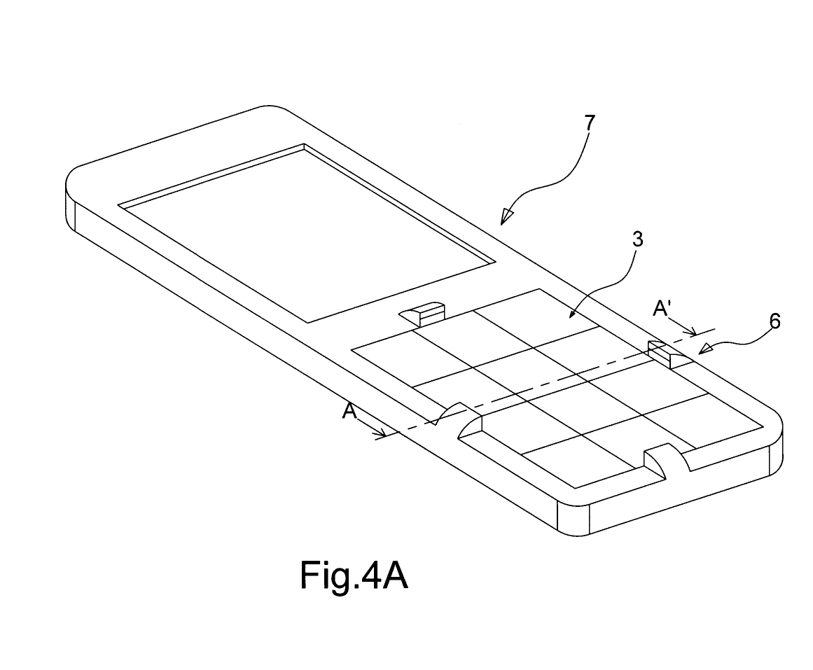

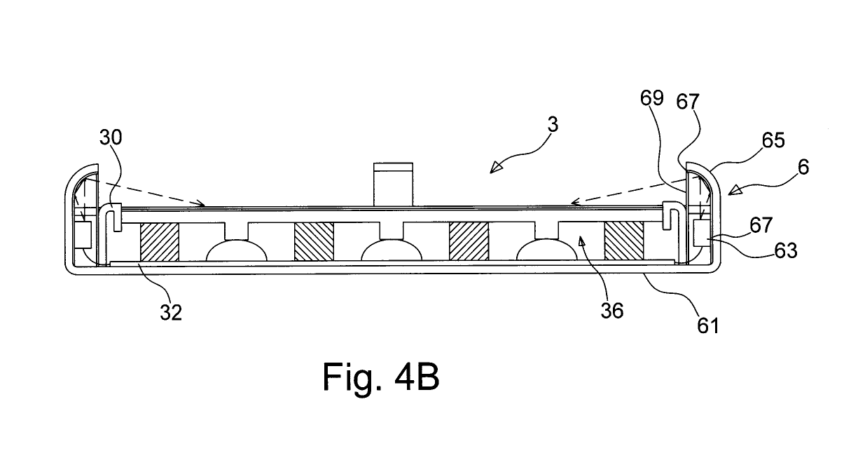

Refer to FIG. 4A & FIG. 4B, a keypad 3 with a lighting device 6 of an embodiment according to the present invention is disclosed. The lighting device 6 includes an outer housing 61 and a plurality of lighting members 63. The fixing frame 30 of the keypad 3 is disposed inside the outer housing 61. The difference between the outer housing 61 of this embodiment and the outer housing 51 of the lighting device 5 of above embodiment is in that the outer housing 61 having a plurality of cup-like members 65. The button set 36 and the circuit board 32 are arranged inside the outer housing 61 and the lighting members 63 are electrically connected with the circuit board 32 and are disposed on the outer housing 61, around the button set 36. The lighting members 63 respectively correspond to the cup-like members 65 of the outer housing 61. Light from the lighting members 63 is reflected by inner surface of the cup-like member 65 and then projected onto the button set 36. A reflective piece 67 is disposed on one side of the cup-like member 65 as well as the outer housing 61 that corresponds to the button set 36 for increasing reflecting efficiency and reducing light loss. And a light homogenizing piece 69 is added on the cup-like member 65 so as to homogenize the projected light and thus the light is projected onto the button set 36 evenly.

In addition, the keypad 3 of the embodiment in FIG. 4A & FIG. 4B can be replaced by the keypad 1 of the embodiment in FIG. 1A. Similarly, the keypad 1 of the embodiment in FIG. 3A & FIG. 3B can be replaced by the keypad 3 of the embodiment in FIG. 2A.

In summary, a keypad with leather or cloth disposed on the button set according to the present invention provides better sense of touch and prevents the figures thereon from being worn or falling off. Thus the aesthetic appeal of the keypad is increased and users have good feelings about the device after using the device. Moreover, a supporting frame is disposed on the button set so as to prevent the buttons with leather or cloth from moving along with the buttons being pressed. Furthermore, a lighting device is added on the keypad for projecting light onto surface of the keypad so that users can read icons on surface of the keypad clearly.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A keypad comprising:
a circuit board,
a plurality of metal domes disposed on and electrically coupled with the circuit board; and
a button set having a plurality of buttons that are respectively corresponding to the metal domes while a piece of leather or cloth is disposed on surface of the button set.

2. The keypad as claimed in claim 1, wherein the keypad further comprising: a fixing frame for fixing the button set.

3. The keypad as claimed in claim 2, wherein the fixing frame is a housing.

4. The keypad as claimed in claim 1, wherein the key pad further comprising:
a supporting frame having a plurality of holes disposed on the button set; the holes respectively correspond to the buttons of the button set while the leather or cloth is disposed on the buttons and the supporting frame.

5. The keypad as claimed in claim 4, wherein the supporting frame is made from polycarbonate (PC).

6. The keypad as claimed in claim 1, wherein the leather or cloth is glued or is sewed on the button set.

7. The keypad as claimed in claim 1, wherein the keypad further comprising: a plurality of projecting posts respectively arranged on the buttons.

8. The keypad as claimed in claim 7, wherein the projecting posts are integrated with the buttons.

9. The keypad as claimed in claim 1, wherein the keypad further comprising: a figure layer arranged on the leather or cloth and having a plurality of figures respectively correspond to the buttons.

10. The keypad as claimed in claim 9, wherein the figure layer is arranged on the leather or cloth by laser marking, or branding.

11. The keypad as claimed in claim 1, wherein the button set is made from rubber.

12. The keypad as claimed in claim 1, wherein the keypad further comprising: a lighting device that projects light onto surface of the button set.

13. The keypad as claimed in claim 12, wherein the lighting device comprising:
an outer housing for accommodating the circuit board and the button set while a side wall of the housing extends to form a circular reflection plane; and
a plurality of light emitting members disposed on the outer housing, around the button set.

14. The keypad as claimed in claim 13, wherein the keypad further comprising:
a fixing frame for fixing the keypad installed inside the outer housing.

15. The keypad as claimed in claim 13, wherein a reflecting piece is arranged on one side of the circular reflection plane that corresponds to the button set

16. The keypad as claimed in claim 13, wherein a reflecting piece is arranged on one side of the outer housing that corresponds to the button set.

17. The keypad as claimed in claim 13, wherein a light homogenizing piece is disposed on the circular reflection plane

18. The keypad as claimed in claim 12, wherein the lighting device comprising:
an outer housing for accommodating the circuit board and the button set and the housing having a plurality of cup-like members; and
a plurality of light emitting members disposed on the outer housing, around the button set and the light emitting members correspond to the cup-like members.

19. The keypad as claimed in claim 18, wherein the keypad further comprising:
a fixing frame for fixing the keypad disposed inside the outer housing.

20. The keypad as claimed in claim 18, wherein a reflecting piece is arranged on inner side of the cup-like member.

21. The keypad as claimed in claim 18, wherein a reflecting piece is disposed on one side wall of the outer housing that corresponds to the button set.

22. The keypad as claimed in claim 18, wherein a light-homogenizing piece is disposed on the cup-like member.

23. A keypad comprising:
an outer housing;
a circuit board disposed inside the outer housing;
a plurality of metal domes disposed on and electrically coupled with the circuit board;
a button set disposed inside the outer housing and having a plurality of buttons that are respectively corresponding to the metal domes while a piece of leather or cloth is disposed on surface of the button set; and
a plurality of light emitting members for projecting light onto surface of the button set arranged on the outer housing, around the button set.

24. The keypad as claimed in claim 23, wherein the keypad further comprising:
a supporting frame having a plurality of holes disposed on the button set; the holes respectively correspond to the buttons of the button set while the leather or cloth is disposed on the buttons and the supporting frame.

25. The keypad as claimed in claim 24, wherein the supporting frame is made from polycarbonate (PC).

26. The keypad as claimed in claim 23, wherein the outer housing further comprising:
a fixing frame for fixing the button set arranged inside the outer housing.

27. The keypad as claimed in claim 23, wherein the leather or cloth is glued or sewed on the button set.

28. The keypad as claimed in claim 23, wherein the keypad further comprising: a plurality of projecting posts respectively arranged on the buttons.

29. The keypad as claimed in claim 28, wherein the projecting posts are integrated with the buttons.

30. The keypad as claimed in claim 23, wherein the keypad further comprising: a figure layer arranged on the leather or cloth and having a plurality of figures respectively correspond to the buttons.

31. The keypad as claimed in claim 30, wherein the figure layer is arranged on the leather or cloth by laser marking, or branding.

32. The keypad as claimed in claim 23, wherein the button set is made from rubber.

33. The keypad as claimed in claim 23, wherein a side wall of the outer housing extends to form a circular reflection plane.

34. The keypad as claimed in claim 33, wherein

35. The keypad as claimed in claim 33, wherein a light-homogenizing piece is disposed on the circular reflection plane.

36. The keypad as claimed in claim 23, wherein a reflecting piece is disposed on one side wall of the outer housing that corresponds to the button set.

37. The keypad as claimed in claim 23, wherein the outer housing having a plurality of cup-like members which respectively correspond to the light emitting members.

38. The keypad as claimed in claim 37, wherein a reflecting piece is arranged on inner side of the cup-like member.

39. The keypad as claimed in claim 37, wherein a light-homogenizing piece is disposed on the cup-like member.

40. The keypad as claimed in claim 23, wherein a reflecting piece is disposed on one side wall of the outer housing that corresponds to the button set.
